(19) United States
(12) Patent Application Publication
(10) Pub. No.: US 2006/0188794 A1
(43) Pub. Date: Aug. 24, 2006

(54) Color conversion film and multicolor light-emitting device provided with the same

(75) Inventor: Takayuki Shimamura, Takatsuki-Shi (JP)

Correspondence Address: HAMRE, SCHUMANN, MUELLER & LARSON, P.C., P.O. BOX 2902-0902, MINNEAPOLIS, MN, 55402, US

(73) Assignee: Matsushita Toshiba Picture Display Co., Ltd., Takatsuki-shi (JP)

(21) Appl. No.: 11/355,864

(22) Filed: Feb. 16, 2006

(30) Foreign Application Priority Data
Feb. 21, 2005 (JP) 2005-044271

(51) Int. Cl. G03F 1/00

(52) U.S. Cl. 430/7

(57) ABSTRACT

A color conversion film of the present invention is formed of a color-conversion material composition containing: an organic solvent having a pyrrolidone group represented by the following formula (I) (component A); a resin material containing at least one of optically active or inactive translucent monomer, oligomer and polymer (component B); and at least one type of phosphor (component C). A multicolor light-emitting device of the present invention includes a light-emitting device and a translucent substrate provided thereon, in which the color conversion film is provided between the light-emitting device and the translucent substrate. Thereby, a color conversion film with an improved color-conversion efficiency and a multicolor light-emitting device provided with such a color conversion film can be provided.

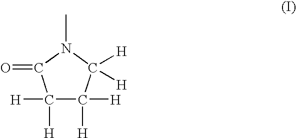

### BACKGROUND OF THE INVENTION

1. Field of the Invention

The present invention relates to a color conversion film and a multicolor light-emitting device provided with the same.

2. Description of Related Art

In recent years, electronic display devices visualizing information have been attracting attention along with the development of information communication. Such electronic display devices include cathode-ray tubes (CRT), plasma displays (PDP), electro-luminescence displays (ELD), liquid crystal displays (LCD) and the like.

Herein, three methods have been examined mainly as methods for implementing full-color electronic display devices. The first method is to arrange multicolor light-emitting portions separately in a plane so as to allow the respective color portions to emit light. This method, however, requires arranging three types of light-emitting materials in a high definition matrix, thus involving the technical difficulties in some light-emitting materials and making it more difficult to reduce the manufacturing cost.

In the second method, a color filter is used with a backlight emitting white light so as to let three primary colors (RGB) of light pass therethrough. According to this method, however, the energy of light captured through each pixel is one-third of the white backlight at most, so that this method has a problem of a low energy efficiency.

In the third method, single-color light is received with a plurality of color conversion films (e.g., a color filter and phosphor) to disperse or convert the light so as to allow different light emission. According to this method, there is no need to arrange light-emitting materials separately, thus simplifying the manufacturing process. Further, since this method has an advantage of a good energy efficiency because of a reduced optical loss, this method is considered to be a promising method for implementing full-color display.

As a patterning method for a color conversion film, a film of a color-conversion material composition containing a phosphor dispersed in a photo-setting resin is formed by spin coating, for example, followed by patterning by photolithography. As another method, screen printing is available. An example of the color-conversion material composition includes a composition containing a binder resin made of a methacrylic ester-methacrylic acid copolymer, at least one type of fluorescent dye and a monomer and/or oligomer having a photopolymerizable ethylene unsaturated group, for example, as disclosed in JP 2003-64135 A. As another example, a composition containing a photo-setting or photothermal-setting resin, an organic fluorescent dye, a high boiling point solvent including a group selected from the group consisting of a hydroxyl group and a carbonyl group is available, as disclosed in JP 3463866 B.

However, the above-mentioned conventional technology has a problem of a poor color-conversion efficiency. The following describes reasons therefor. In general, as a the density of phosphor is increased, a phenomenon called concentration quenching occurs, in which the movement of the absorbed excitation energy is repeated among the same type of phosphors, resulting in a failure of light-emission and causing deactivation of the energy. Therefore, a phosphor should be dispersed appropriately in a medium. However, according to the above-mentioned conventional technology, since the dispersion property of the phosphor is low, the color-conversion efficiency will be degraded.

### SUMMARY OF THE INVENTION

Therefore, in order to solve the above-mentioned conventional problems, it is an object of the present invention to provide a color conversion film with an improved color-conversion efficiency and a multicolor light-emitting device provided with the same.

A color conversion film of the present invention is formed of a color-conversion material composition containing: an organic solvent having a pyrrolidone group represented by the following formula (I) (component A); a resin material containing at least one of optically active or inactive translucent monomer, oligomer and polymer (component B); and at least one type of phosphor (component C).

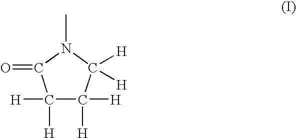

The above-stated color conversion film preferably includes 0.01 to 50 weight % of the component A with respect to a weight of the color conversion film.

Another color conversion film of the present invention is formed of a color-conversion material composition containing: a monomer having a pyrrolidone group represented by the above general formula (I) and a photopolymerizable ethylene unsaturated group (component D); a resin material containing at least one of translucent monomer and oligomer having a photopolymerizable ethylene unsaturated group (component E); and at least one type of phosphor (component C).

The above-stated color conversion film preferably includes 0.01 to 50 weight % of the component D with respect to a weight of the color conversion film.

A multicolor light-emitting device of the present invention includes a light-emitting device and a translucent substrate provided thereon, in which the above-stated color conversion film is provided between the light-emitting device and the translucent substrate so as to allow multicolor light to be emitted.

### BRIEF DESCRIPTION OF THE DRAWINGS

FIG. 1 is a cross-sectional view of a multicolor light-emitting device in one embodiment of the present invention.

FIG. 2 is a cross-sectional view showing a light-emitting member that is an inorganic EL in a multicolor light-emitting device of one embodiment of the present invention.

### DETAILED DESCRIPTION OF THE INVENTION

A color conversion film of the present invention includes a phosphor dispersed favorably so as to decrease concentration quenching, and therefore a color conversion film with an improved color-conversion efficiency and a multicolor light-emitting device can be provided.

### Embodiment 1

A color conversion film of the present invention is formed of a color-conversion material composition containing an organic solvent having a pyrrolidone group represented by the general formula (I) (component A), a resin material containing at least one type of optically active or inactive translucent monomer, oligomer and polymer (component B), and at least one type of phosphor (component C).

In the color conversion film of the present invention, a matrix resin formed of the component B contains a solvent of the component A, in which a phosphor of the component C further is dispersed. In general, a matrix resin has to have an appropriate polarity in order to allow a phosphor to disperse therein. In this regard, in the case where a matrix resin contains an organic solvent including a pyrrolidone group as a polar group, the dispersion property of the phosphor becomes remarkably favorable, thus resulting in an improvement in a color-conversion efficiency of the color conversion film of the present invention.

The following describes the respective components in detail. The component A may be any organic solvent as long as it has a pyrrolidone group, which may include N-methyl-2-pyrrolidone and its derivative, for example. N-methyl-2-pyrrolidone and its derivative can be represented by the following general formula (II):

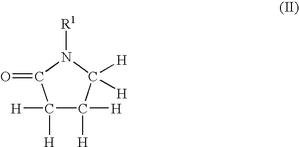

where R¹ denotes an alkyl group with a carbon number of 1 to 10.

The content of the component A preferably is 0.01 to 50 weight % with respect to the entire color conversion film. When the content of the component A is less than 0.01 weight %, the effect of improving the phosphor dispersion property is small. Further, since the pyrrolidone group is hydrophilic, a color conversion film formed of the component A exceeding 50 weight % tends to absorb water. In general many phosphors are vulnerable to water, and therefore the absorption of water will cause deterioration of the color-conversion efficiency.

Examples of the monomer used as the component B include acrylate, methacrylate, a vinyl monomer and the like. More specifically, they include allylmethacrylate, butanediol monoacrylate, tripropylene glycol diacrylate, hexanediol diacrylate, tetraethylene glycol diacrylate, dicyclo pentanyl diacrylate, polyethylene glycol diacrylate, trimethylolpropane triacrylate, pentaerythritol triacrylate, pentaerythritol tetraacrylate, 2-hydroxyethylacrylate, vinyl chloride, vinyl acetate, styrene and the like. Examples of the oligomer used as the component B include epoxy acrylate, urethane acrylate, polyether acrylate, polyester acrylate, vinyl ester and the like. Examples of the polymer used as the component B include a methacrylic ester-methacrylic acid copolymer as disclosed in JP 2003-64135 A, as well as an acrylic resin, an epoxy resin, a melamine resin, a benzoguanamine resin and the like. They may be used alone or as a mixture. When patterning is performed by photolithography, an optically active resin material has to be used, and when development is performed using an alkali aqueous solution, the above-mentioned resin material preferably is soluble in alkali.

A fluorescent dye or a fluorescent pigment may be used as a phosphor of the component C. Examples of the fluorescent dye emitting a green fluorescence include a coumarin based dye such as 3-(2′-benzothiazolyl)-7-N, N-diethylaminocoumarin (coumarin 540) and a naphthalic imide based dye such as solvent yellow-11. Examples of the fluorescent dye emitting a red fluorescence include a rhodamine based dye such as rhodamine 6G and a cyanine based dye such as 4-dicyanomethylene-2-methyl-6-(p-dimethylaminostillyl)-4H-pyran (DCM). Examples of the fluorescent pigment include an organic fluorescent pigment obtained by kneading a fluorescent dye in a benzoguanamine resin or an inorganic fluorescent pigment such as SrGa₂S₄:Eu and CaS:Eu. These phosphors may be used alone or as a mixture as needed. Assuming that the entire color conversion film is 100 weight % in terms of a solid material, 0.1 to 70 weight % of the phosphor (the component C) preferably is contained.

A photo polymerization initiator or a sensitizer may be added as needed to the color-conversion material composition for forming a color conversion film of the present invention. This photo polymerization initiator or sensitizer is used not only for the photo-setting reaction of the component B but also as a polymerization initiator of a photopolymerizable unsaturated compound such as (meta) acrylic monomer or (meta) acrylic oligomer. As such a photo polymerization initiator, acetonephenones, benzophenones and the like are used favorably.

As specific examples of these, acetonephenones include acetonephenone, 2,2-diethoxy acetonephenone and the like, and benzophenones include benzophenone, p,p′-bisdimethylamino benzophenone and the like. Regarding the photo polymerization initiator and sensitizer, one type may be used alone or they may be used in combinations of two or more types.

Further, a compound that does not function singly as a photo polymerization initiator or a sensitizer but can augment the ability of a photo polymerization initiator or a sensitizer in combination with the above-stated compound can be added. Examples of such a compound include tertiary amine such as triethanolamine that is effective in combination with benzophenone.

Additives such as a curing accelerator, a thermal polymerization inhibitor, a plasticizer, a filler, a solvent, an antifoaming agent and a leveling agent further may be added as needed to the color-conversion material composition for forming the color conversion film of the present invention. Preferable examples of the curing accelerator include a perbenzoic acid derivative, peracetic acid and benzophenone. Preferable examples of the thermal polymerization inhibitor include hydroquinone and hydroquinone monomethylether. Preferable examples of the plasticizer include dibutyl phthalate, dioctyl phthalate and tricresyl. Preferable examples of the filler include glass fiber, silica, mica and alumina. Preferable examples of the antifoaming agent and the leveling agent include silicon-based, fluorine-based and acrylic-based compounds.

Further, the above various additive components to the color-conversion material composition may be dissolved in a solvent depending on the method of manufacturing the color conversion film. As the solvent, ketones, cellosolves and lactones may be used, for example. More specifically, methyl ethyl ketone, methyl isobutyl ketone, cyclohexanone and the like may be used as the ketones, methyl cellosolve, ethyl cellosolve, butyl cellosolve, cellosolve acetate and the like may be used as the cellosolves, and γ-butyrolactone and the like may be used as the lactones preferably.

The color conversion film of the present invention absorbs light from a light source and emits light of a longer wavelength. The color conversion film of the present invention is formed using the above-stated color-conversion material composition, which is cured or undergoes photolithography. Particularly, the formation by photolithography is preferable. The color conversion film of the present invention may be manufactured by a conventional method as follows. Firstly, the above-stated photosensitive color-conversion material composition is prepared as a solution and is applied to a surface of a substrate. Next, most of the solvent is removed (prebaked) by precuring, and a photomask is applied on the obtained coating, followed by the irradiation with an activation light beam to cure an exposure part. Further, development is performed by dissolving an uncured part using a weak alkaline solution, followed by postbaking.

As the substrate to which the color-conversion material composition for forming the color conversion film of the present invention is applied, a smooth substrate having a transmittance of light in the visible region of 400 to 700 nm of 50% or more preferably is used. More specifically, a glass substrate and a polymer plate may be used. As a method for applying the solution of the color-conversion material composition of the present invention on the substrate, any method such as using a roller coater, a land coater or a spinner may be used in addition to well-known methods of dipping in a solution and spraying. The solution is applied by these methods to have a desired thickness, followed by removal of most of the solvent (prebaking), whereby a coating can be formed.

This prebaking can be performed by heating with an oven, a hot plate or the like. A heating temperature and heating time for prebaking can be selected appropriately depending on a solvent used, and for example, prebaking can be preformed at 80 to 150° C. for 1 to 30 minutes. Exposure after prebaking is performed by an exposure apparatus, in which by exposure through a photomask, only a resist residing at a portion corresponding to a pattern can be exposed to light. The exposure apparatus and the exposure and irradiation conditions can be selected appropriately, and visible light, UV light, X-rays, electron beams and the like can be used as the light for irradiation. The irradiation amount is not limited especially, and the range of 1 to 3,000 mJ/cm² can be selected, for example.

Alkaline development after the exposure is performed for the purpose of removing the resist residing at the portion that was not exposed to light. As a result of this development, a desired pattern can be formed. As a developer suitable for this alkaline development, an aqueous solution of a carbonate of alkali metal and alkaline-earth metal can be used, for example. Particularly, a weak alkaline aqueous solution containing 1 to 3 weight % of a carbonate of sodium carbonate, potassium carbonate, lithium carbonate and the like preferably is used at a temperature of 10 to 50° C., 20 to 40° C. preferably, for development, so that a fine image can be formed accurately using a commercially available developing machine, an ultrasonic cleaner or the like.

After such development, a heat treatment (postbaking) is performed under the conditions of 80 to 170° C. for 10 to 120 minutes. This postbaking is performed for the purpose of enhancing the adhesiveness between the color conversion film subjected to patterning and the substrate. This can be performed by heating with an oven, a hot plate or the like similarly to the prebaking. The color conversion film of the present invention, subjected to patterning, can be formed by the following respective steps of so-called photolithography.

The film thickness of the color conversion film of the present invention has to be selected appropriately so as to allow incident light to be converted to have a desired wavelength. Normally, the range of 1 to 100 μm is selected. Particularly, a film thickness of 1 to 20 μm is preferable. Further, in order to obtain a desired wavelength, a color filter may be provided concurrently for adjusting color purity. As the color filter, a dye including a perylene-based pigment, a lake-based pigment, an azo-based pigment, a quinacridon-based pigment, an anthraquinone-based pigment, an anthracene-based pigment, an isoindolin-based pigment, an isoindolinone-based pigment, a phthalocyanine-based pigment, a triphenylmethane-based pigment, an indanthrone-based pigment, an indophenol-based pigment, a cyanine-based pigment, a dioxazine-based pigment and the like can be used alone or as a mixture of two or more types of them. A solid-state member in which a dye is dissolved or dispersed in a binder resin also can be used preferably.

The following shows exemplary configurations in practical applications of the color conversion film of the present invention:

(1) light source/color conversion film; (2) light source/substrate/color conversion film; (3) light source/color conversion film substrate; (4) light source/translucent substrate/color conversion film/substrate; (5) light source/color conversion film/color filter; (6) light source/substrate/color conversion film/color filter; (7) light source/color conversion film/substrate/color filter; (8) light source/substrate/color conversion film/substrate/color filter; (9) light source/substrate/color conversion film/color filter/substrate; (10) light source/color conversion film/color filter/substrate, etc., When using these configurations, the respective constituent elements can be laminated successively, or can be bonded to each other. The lamination order of this color conversion film is not limited especially, and the lamination can be performed from either side, i.e., from left to right or from right to left.

As a light source for this color conversion film, an inorganic EL is preferable because of its low profile, surface emitting and long life characteristics. However, light sources such as an organic EL, a LED and a PDP also can be used.

The following describes a typical configuration of the inorganic EL element used for the present invention. The inorganic EL element has at least a light-emitting layer between two opposed electrodes. At least one of the above-stated electrodes has to be a transparent electrode, and a transparent electrode layer made of an indium-tin oxide alloy (ITO) of 0.1 to 0.5 μm in thickness may be used as the transparent electrode. The light-emitting layer is obtained by forming a layer of a light-emitting material such as an inorganic or organic phosphor. An electrical insulation layer (dielectric layer) may be disposed on both sides or one side of the light-emitting layer. In the case of an inorganic phosphor, a dielectric layer is provided between two opposed electrodes, and light is emitted from the light-emitting layer made of phosphor by applying an electric field using a principle of a capacitor. As the dielectric layer, at least one type selected from Y₂O₃, Li₂O, MgO, CaO, BaO, SrO, Al₂O₃, SiO₂, MgTiO₃, CaTiO₃, BaTiO₃, SrTiO₃, ZrO₂, TiO₂, B₂O₃, PbTiO₃, PbZrO₃ and PbZrTiO₃ (PZT) can be used. Further, a ferroelectric layer may be provided between the two electrodes, so as to enhance a light-emitting efficiency further.

As light-emitting materials that can be used as the light-emitting layer, generally known phosphors may be used, including ZnS:Ag, ZnS:Cu, ZnS:Mn, SrS:Ce:Eu, ZnS:Sm:Cl, CaS:Eu, ZnS:Tb:F, CaS:Ce, ZeMgS:Mn, CaGa₂S₄:Ce, SrS:Cu, CaS:Pb, BaAl₂S₄:Eu, Y₂O₃:Eu, Ca₂Ge₂O₇:Mn and the like.

### Embodiment 2

A color conversion film of the present embodiment is formed of a color-conversion material composition containing a monomer having a pyrrolidone group represented by the general formula (I) and a photopolymerizable ethylene unsaturated group (component D), a resin material containing at least one type of translucent monomer and oligomer having a photopolymerizable ethylene unsaturated group (component E) and at least one type of phosphor (component C).

In the color conversion film of the present embodiment, a phosphor is dispersed in a matrix resin formed by copolymerization of the component D and the component E. In Embodiment 1, the component A and the component B simply are mixed and are not combined chemically. Therefore, as the amount of the component A changes over time, the dispersion property of the phosphor changes over time as well. According to the color conversion film of the present embodiment, however, the component D having a pyrrolidone group is combined chemically with the component E, and therefore the present embodiment has an advantage of a small change in the dispersion property over time.

The following describes the respective components in detail. In the following, only the component D and the component E, which are different from Embodiment 1, are described in detail, and other components and their manufacturing process are omitted because they are the same as in Embodiment 1. The component D may be any monomer as long as it has a pyrrolidone group and a photopolymerizable ethylene unsaturated group. For example, the component D includes N-vinyl-2-pyrrolidone and its derivative. N-vinyl-2-pyrrolidone and its derivative can be represented by the following general formula (III):

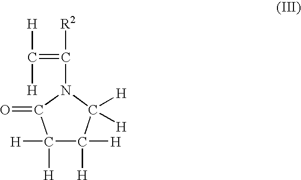

where R² denotes a hydrogen atom or an alkyl group with a carbon number of 1 to 10.

The amount of the component D added preferably is 0.01 to 50 weight % with respect to the entire color-conversion material composition. When the added amount of the component D is less than 0.01 weight %, the effect of improving the phosphor dispersion property will not be obtained. Further, since the pyrrolidone group is hydrophilic, a color conversion film formed of the component D exceeding 50 weight % tends to absorb water. In general many phosphors are vulnerable to water, and therefore the absorption of water will cause a deterioration of a color-conversion efficiency.

Examples of the monomer having a photopolymerizable ethylene unsaturated group as the component E include acrylate, methacrylate, a vinyl monomer and the like. More specifically, they include allylmethacrylate, butanediol monoacrylate, tripropylene glycol diacrylate, hexanediol diacrylate, tetraethylene glycol diacrylate, dicyclo pentanyl diacrylate, polyethylene glycol diacrylate, trimethylolpropane triacrylate, pentaerythritol triacrylate, pentaerythritol tetraacrylate, 2-hydroxyethylacrylate, vinyl chloride, vinyl acetate, styrene and the like. Examples of the oligomer having a photopolymerizable ethylene unsaturated group as the component E include epoxy acrylate, urethane acrylate, polyether acrylate, polyester acrylate, vinyl ester and the like. One type or two or more types of these compounds may be used. Further, an optically active or inactive translucent monomer, oligomer or polymer as mentioned in the component B may added thereto.

### WORKING EXAMPLES

Hereinafter, the present invention will be described by way of specific working examples. The present invention is not limited to the following working examples.

### Example 1

(1) Preparation of a Color-Conversion Composition

A color-conversion composition was obtained by mixing the following components at 40° C. for 20 minutes.

| | |
|---|---|
| (a) component A | |
| N-methyl-2-pyrrolidone | 1 g |
| (b) component B | |
| trimethylolpropane triacrylate (produced by TOAGOSEI | 1.3 g |
| Co., Ltd, M-309) | |
| epoxy acrylate oligomer (produced by SHOWA | 3 g |
| HIGHPOLYMER Co., Ltd, lipoxy SP-2600) | |
| (c) component C | |
| coumarin 540 (produced by Exciton com) | 24 mg |
| (d) solvent | |
| propylene glycol monoethyletheracetate | 2 g |
| (e) others | |
| photo polymerization initiator IRGACURE 369 | 0.1 g |
| (produced by CIBA Specialty Chemicals) | |

(2) Preparation of Color Conversion Film and Inorganic EL

A film of the above-stated color-conversion composition of 20 mm length and 15 mm width in size was formed on a transparent glass substrate of 50 mm length and 50 mm width in size by screen printing. Subsequently, prebaking was performed at 100° C. for 10 minutes, followed by irradiation of UV light (wavelength: 365 nm) of 200 mJ/cm² and then a heat treatment was applied thereto at 120° C. for 10 minutes. Thus, a color conversion film of 15 μm in thickness was obtained.

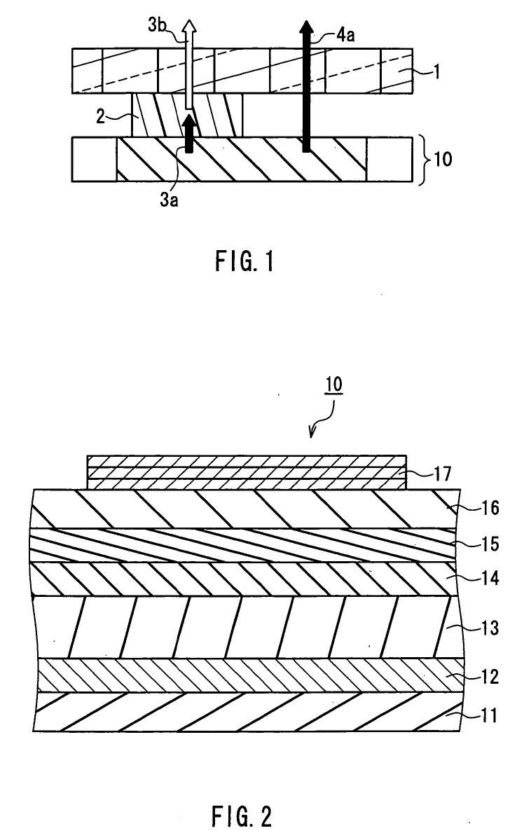

The following is a description with reference to the drawings. FIG. 1 is a cross-sectional view of a multicolor light-emitting device in Example 1 of the present invention. A color conversion film 2 is formed on a translucent substrate 1. Alight-emitting member 10, which is an inorganic EL manufactured by a separate process, is laid over that.

FIG. 2 is a cross-sectional view showing the light-emitting member 10 that is an inorganic EL in one example of the present invention. Firstly, a back electrode 12 made of copper wiring of 0.5 μm in thickness was formed on a back substrate 11 made of Al₂O₃ of 1 mm in thickness. A dielectric layer 13 made of BaTiO₃ of 30 μm in thickness, a smoothing layer 14 made of BaTiO₃ organic acid of 0.6 μm in thickness, a phosphor light-emitting layer 15 made of BaAl₂S₄:Eu of 0.6 μm in thickness and a dispersion-inhibiting layer 16 made of Al₂O₃ of 0.5 μm in thickness were formed thereon. A transparent electrode 17 made of indium-tin oxide alloy (ITO) layer (refractive index n=2.1) of 0.5 μm in thickness was formed thereon.

### Example 2

A color conversion film and a multicolor light-emitting device were manufactured similarly to Example 1 except that a color-conversion composition was obtained by mixing the following components at 40° C. for 20 minutes.

| | |
|---|---|
| (a) component A | |
| N-methyl-2-pyrrolidone | 1 g |
| (b) component B | |
| trimethylolpropane triacrylate (produced by TOAGOSEI Co., | 1.3 g |
| Ltd, M-309) | |
| epoxy acrylate oligomer (produced by SHOWA | 3 g |
| HIGHPOLYMER Co., Ltd, lipoxy SP-2600) | |
| (c) component C | |
| fluorescent pigment (produced by SINLOIHI Co., Ltd, | 1 g |
| FZ-5005) | |
| (d) solvent | |
| propylene glycol monoethyletheracetate | 2 g |
| (e) others | |
| photo polymerization initiator IRGACURE 369 (produced by | 0.1 g |
| CIBA Specialty Chemicals) | |

### Example 3

A color conversion film and a multicolor light-emitting device were manufactured similarly to Example 1 except that a color-conversion composition was obtained by mixing the following components at 40° C. for 20 minutes.

| | |
|---|---|
| (a) component D | |
| N-vinyl-2-pyrrolidone (produced by TOAGOSEI Co., Ltd, | 1 g |
| M-150) | |
| (b) component E | |
| trimethylolpropane triacrylate (produced by TOAGOSEI Co., | 1.3 g |
| Ltd, M-309) | |
| epoxy acrylate oligomer (produced by SHOWA | 3 g |
| HIGHPOLYMER Co., Ltd, lipoxy SP-2600) | |
| (c) component C | |
| coumarin 540 (produced by Exciton com) | 24 mg |
| (d) solvent | |
| propylene glycol monoethyletheracetate | 2 g |
| (e) others | |
| photo polymerization initiator IRGACURE 369 (produced by | 0.1 g |
| CIBA Specialty Chemicals) | |

### Example 4

A color conversion film and a multicolor light-emitting device were manufactured similarly to Example 1 except that a color-conversion composition was obtained by mixing the following components at 40° C. for 20 minutes.

| | |
|---|---|
| (a) component D | |
| N-vinyl-2-pyrrolidone (produced by TOAGOSEI Co., Ltd, | 1 g |
| M-150) | |
| (b) component E | |
| trimethylolpropane triacrylate (produced by TOAGOSEI | 1.3 g |
| Co., Ltd, M-309) | |
| epoxy acrylate oligomer (produced by SHOWA | 3 g |
| HIGHPOLYMER Co., Ltd, lipoxy SP-2600) | |
| (c) component C | |
| fluorescent pigment (produced by SINLOIHI Co., Ltd, | 1 g |
| FZ-5005) | |
| (d) solvent | |
| propylene glycol monoethyletheracetate | 2 g |
| (e) others | |
| photo polymerization initiator IRGACURE 369 (produced | 0.1 g |
| by CIBA Specialty Chemicals) | |

### Comparative Example 1

A color conversion film and a multicolor light-emitting device were manufactured similarly to Example 1 except that a color-conversion composition was obtained by mixing the following components at 40° C. for 20 minutes.

| | |
|---|---|
| (a) component A | |
| none | |
| (b) component B | |
| trimethylolpropane triacrylate (produced by TOAGOSEI | 1.3 g |
| Co., Ltd, M-309) | |
| epoxy acrylate oligomer (produced by SHOWA | 3 g |
| HIGHPOLYMER Co., Ltd, lipoxy SP-2600) | |
| (c) component C | |
| coumarin 540 (produced by Exciton com) | 24 mg |
| (d) solvent | |
| propylene glycol monoethyletheracetate | 2 g |
| diethylene glycol monoethylether | 1 g |
| (e) others | |
| photo polymerization initiator IRGACURE 369 (produced | 0.1 g |
| by CIBA Specialty Chemicals) | |

### Comparative Example 2

A color conversion film and a multicolor light-emitting device were manufactured similarly to Example 1 except that a color-conversion composition was obtained by mixing the following components at 40° C. for 20 minutes.

| | |
|---|---|
| (a) component A | |
| none | |
| (b) component B | |
| trimethylolpropane triacrylate (produced by TOAGOSEI Co., | 1.3 g |
| Ltd, M-309) | |
| epoxy acrylate oligomer (produced by SHOWA | 3 g |
| HIGHPOLYMER Co., Ltd, lipoxy SP-2600) | |
| (c) component C | |
| fluorescent pigment (produced by SINLOIHI Co., Ltd, FZ-5005) | 1 g |
| (d) solvent | |
| propylene glycol monoethyletheracetate | 2 g |
| diethylene glycol monoethylether | 1 g |
| (e) others | |
| photo polymerization initiator IRGACURE 369 (produced | 0.1 g |
| by CIBA Specialty Chemicals) | |

[Evaluations]

The multicolor light-emitting devices manufactured in the respective Examples and Comparative examples were turned ON by applying an alternating voltage at 1 kHz with the effective voltage of 200 V, and as shown in FIG. 1 the brightness of a light beam 3b obtained from the color conversion film 2 and the brightness of a light beam 4a obtained from the light-emitting member 10 that did not pass through the color conversion film 2 were measured. The measurement was conducted using a spectrometer (MCPD-2000, produced by Ohtsuka Optical Co., Ltd). The color conversion efficiency of the color conversion film 2 was calculated from the following equation.
Color conversion efficiency (%)=(brightness of light passed through color conversion film 2/brightness of light that did not pass through color conversion film 2)×100

Table 1 shows the obtained results. In comparing Example 1, Example 3 and Comparative example 1, the color conversion efficiencies of Example 1 containing the component A and of Example 3 containing the component D were higher than that of Comparative example 1. Similarly, the color conversion efficiencies of Example 2 containing the component A and of Example 4 containing the component D were higher than that of Comparative example 2.

TABLE 1

| Examples | Color |
|---|---|
| Comparative | conversion |
| Examples No. | efficiency (%) |
| Ex. 1 | 108 |
| Ex. 2 | 110 |
| Ex. 3 | 108 |
| Ex. 4 | 112 |
| Comp. Ex. 1 | 84 |
| Comp. Ex. 2 | 91 |

As is evident from Table 1, the color conversion efficiencies of Examples of the present invention were improved by about 20 to 30% as compared with Comparative Examples.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A color conversion film comprising a color-conversion material composition comprising:
an organic solvent having a pyrrolidone group represented by the following formula (I) (component A);
a resin material comprising at least one of optically active or inactive translucent monomer, oligomer and polymer (component B); and
at least one type of phosphor (component C)

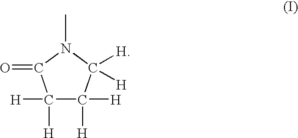

2. The color conversion film according to claim 1, comprising 0.01 to 50 weight % of the component A with respect to a weight of the color conversion film.

3. The color conversion film according to claim 1,
wherein the organic solvent having pyrrolidone group (component A) in the formula (I) and its derivative are represented by the following general formula (II): 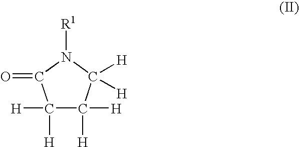
where R¹ denotes an alkyl group with a carbon number of 1 to 10.

4. A color conversion film comprising a color-conversion material composition comprising:
a monomer having a pyrrolidone group represented by the following general formula (I) and a photopolymerizable ethylene unsaturated group (component D);
a resin material comprising at least one of translucent monomer and oligomer having a photopolymerizable ethylene unsaturated group (component E); and
at least one type of phosphor (component C)

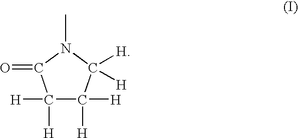

5. The color conversion film according to claim 4, comprising 0.01 to 50 weight % of the component D with respect to a weight of the color conversion film.

6. The color conversion film according to claim 4, wherein the monomer having a pyrrolidone group represented by the general formula (I) and a photopolymerizable ethylene unsaturated group (component D) is represented by the following general formula (III): 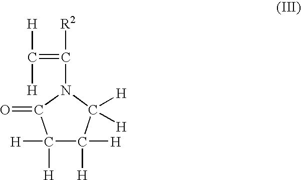
where R² denotes a hydrogen atom or an alkyl group with a carbon number of 1 to 10.

7. A multicolor light-emitting device, comprising a light-emitting device and a translucent substrate provided on the light-emitting device,
wherein a color conversion film made of a color-conversion material composition is disposed on a surface of the translucent substrate, the color-conversion material composition comprising:
an organic solvent having a pyrrolidone group represented by the following formula (I) (component A);
a resin material comprising at least one of optically active or inactive translucent monomer, oligomer and polymer (component B); and
at least one type of phosphor (component C),
wherein the color conversion film is provided between the light-emitting device and the translucent substrate so as to allow multicolor light to be emitted

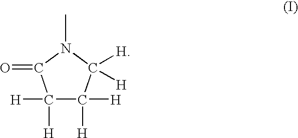

8. A multicolor light-emitting device, comprising a light-emitting device and a translucent substrate provided on the light-emitting device,
wherein a color conversion film made of a color-conversion material composition is disposed on a surface of the translucent substrate, the color-conversion material composition comprising:
a monomer having a pyrrolidone group represented by the following general formula (I) and a photopolymerizable ethylene unsaturated group (component D);
a resin material comprising at least one of translucent monomer and oligomer having a photopolymerizable ethylene unsaturated group (component E); and
at least one type of phosphor (component C),
wherein the color conversion film is provided between the light-emitting device and the translucent substrate so as to allow multicolor light to be emitted

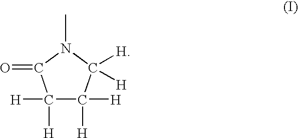

9. The multicolor light-emitting device according to claim 8, wherein 0.01 to 50 weight % of the component D is included with respect to a weight of the color conversion film.
